(19) United States
(12) Patent Application Publication
(10) Pub. No.: US 2026/0262476 A1
(43) Pub. Date: Sep. 3, 2026

(54) GRIPPER FOR TRANSPORTING AN UPRIGHT SEMICONDUCTOR WAFER AND METHOD FOR CLEANING THE SEMICONDUCTOR WAFER

(71) Applicant: SILTRONIC AG, Munich (DE)

(72) Inventors: Bertram MÖCKEL, Freiberg (DE); Roland BRUNNER, Reut (DE); Jonny FRANKE, Eppendorf (DE); Ludwig LAMPRECHT, Truchtlaching (DE); Simon ROTHENAICHER, Erlbach (DE)

(21) Appl. No.: 18/871,495

(22) PCT Filed: May 31, 2023
(86) PCT No.: PCT/EP2023/064494

§ 371 Date: Dec. 4, 2024

(30) Foreign Application Priority Data
Jun. 7, 2022 (EP) EP22177526

(51) Int. Cl. H10P 72/76; B25J 11/00; H10P 72/00

(52) U.S. Cl. CPC H10P 72/7602; B25J 11/0095; H10P 72/0411

(57) ABSTRACT

A gripper transports a vertically standing semiconductor wafer. The gripper has: a flat body, having a head section and a foot section, which form a planar front side; and arms, which extend from the head section to spaced-apart ends in the foot section. At end sections of the arms, there is a supporting surface, which is arranged so as to be set back from the plane of the front side. Holding pins are arranged on the end sections and are configured to establish a clamping connection between the semiconductor wafer and the body. A channel, which follows an inner side of the arms, is made in the arms, and terminates at end edges.

The end edges are separated from the ends of the arms.

### CROSS REFERENCE TO RELATED APPLICATIONS

This application is a U.S. National Phase application under 35 U.S.C. § 371 of International Application No. PCT/EP2023/064494, filed on May 31, 2023, and claims benefit to European Patent Application No. EP22177526, filed on Jun. 7, 2022. The International Application was published in German on Dec. 14, 2023 as WO 2023/237391 A1 under PCT Article 21(2).

### FIELD

The present disclosure relates to a gripper for transporting a vertically standing semiconductor wafer.

### BACKGROUND

Grippers of this type are used, in particular, in cleaning lines in which semiconductor wafers, following chemical mechanical polishing (CMP), are individually transported into a cleaning module and cleaned. A cleaning line (running beam device) of this type is described, for example, US 2020/0203152 A1. Such a gripper is also referred to as a blade.

CN213 845 245 U discloses such a gripper. The disadvantage here is that this gripper does not sufficiently protect a semiconductor wafer, following cleaning, against liquid cleaning agent passing onto the semiconductor wafer from the gripper and particles contained in the cleaning agent thus being able to contaminate the clean semiconductor wafer anew and/or cleaning agent which subsequently passes on to the semiconductor wafer altering the roughness of the surface of the semiconductor wafer.

### SUMMARY

In an embodiment, the present disclosure provides a gripper that transports a vertically standing semiconductor wafer. The gripper has: a flat body, having a head section and a foot section, which form a planar front side; and arms, which extend from the head section to spaced-apart ends in the foot section. At end sections of the arms, there is a supporting surface, which is arranged so as to be set back from the plane of the front side. Holding pins are arranged on the end sections and are configured to establish a clamping connection between the semiconductor wafer and the body. A channel, which follows an inner side of the arms, is made in the arms, and terminates at end edges. The end edges are separated from the ends of the arms.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows the front side of an embodiment according to the present disclosure of the gripper and of the semiconductor wafer transported thereby;

FIG. 2 shows an enlarged detail from FIG. 1;

FIG. 3 shows a view of parts of FIG. 1, which has been rotated by virtually 90° about a vertical axis in the anticlockwise direction;

FIG. 4 shows a further possible configuration of the ends of the arms; and

FIG. 5 shows a possible configuration of the holding pins.

### DETAILED DESCRIPTION

The present disclosure relates to a gripper for transporting a vertically standing semiconductor wafer, comprising a flat body having a head section and a foot section, which form a planar front side; arms, which extend from the head section to spaced-apart ends in the foot section; at end portions of the arms, a supporting surface, which is arranged so as to be set back from the plane of the front side; and holding pins, which are arranged on the end sections and are intended for establishing a clamping connection between the semiconductor wafer and the body.

Aspects of the present disclosure advantageously reduce this risk of the cleaned semiconductor wafer becoming recontaminated.

Advantages provided by embodiments of the present disclosure are achieved by a gripper for transporting a vertically standing semiconductor wafer, comprising a flat body having a head section and a foot section, which form a planar front side; arms, which extend from the head section to spaced-apart ends in the foot section; at end sections of the arms, a supporting surface, which is arranged so as to be set back from the plane of the front side; and holding pins, which are arranged on the end sections and are intended for establishing a clamping connection between the semiconductor wafer and the body, characterized by a channel which follows an inner side of the arms, is made in the arms and terminates at edges, wherein the edges are separated from the ends of the arms.

The disclosed channel directs liquid predominantly past the semiconductor wafer to the (end) edges of the channel, from which the liquid can drip off without passing to the surface of the semiconductor wafer beforehand. The channel preferably extends in the forward direction, that is to say it projects some way towards out of the plane of the front side. It is preferably the case that the inner sides of the arms are curved towards one another in a semi-circular manner. It is also possible for the arms to be shaped in a manner other than this, for example for the arms to be spaced apart from one another at a constant distance in the foot section.

It is also preferred if the arms, at the ends, are each tapered to a point, the latter having no contact with a semiconductor wafer transported by the gripper. The point is preferably rounded. It is also the case with this configuration that liquid can drip off at the points.

The body of the gripper is thicker than the semiconductor wafer which is to be transported, and it preferably consists of a polymer.

Apertures are preferably present in the head section, and these reduce the weight of the gripper and the flow resistance thereof.

The semiconductor wafer preferably consists of a single-crystal silicon and has a diameter of preferably 300 mm or greater.

It is preferably the case that the semiconductor wafer transported by the gripper is at a distance from the supporting surface. The distance is ensured by the configuration of the holding pins. The distance is preferably at least equal to the thickness of the semiconductor wafer. The holding pins preferably each have a resting surface for the semiconductor wafer, this surface being flanked by boundaries. The boundaries are in the form of truncated cones, which are located opposite one another, the base surfaces of the truncated cones being located on the outside.

The present disclosure also relates to a method for cleaning a semiconductor wafer in a cleaning line, wherein the semiconductor wafer is transported in a vertically standing state out of a cleaning module of the cleaning line, characterized in that, during this time, the semiconductor wafer is transported by a gripper according to an embodiment of the present disclosure. The method is preferably used following CMP.

Aspects of the present disclosure will be described in more detail hereinbelow with reference to drawings.

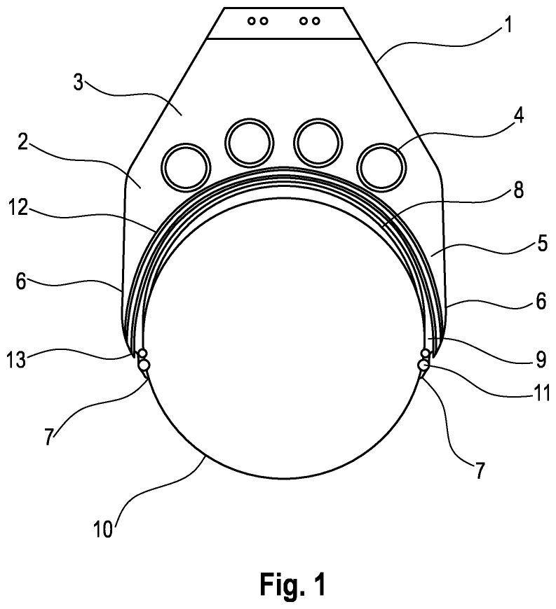

The gripper 1 illustrated in FIG. 1 comprises a flat body 2 having a head section 3 with apertures 4 and a foot section 5, which is formed by arms 6, which extends from the head section 3 to ends 7 in the foot section 5. The arms 6 of this embodiment are curved along an inner side 8 and come together in the head section 3. The head section 3 and the foot section 5 form a planar front side of the body.

A supporting surface 9 is present at the end sections of the arms 6, the supporting surface being arranged so as to be set back from the plane of the front side. Also arranged on the end sections are holding pins 11, with the aid of which a clamping connection is established between the semiconductor wafer 10 and the body 2.

The gripper 1 also has a channel 12, which follows the curvature of the arms 6 and terminates at end edges 13. The channel 12 is made in the body 2 and follows the curvature of the inner side 8 of the arms at a certain distance therefrom.

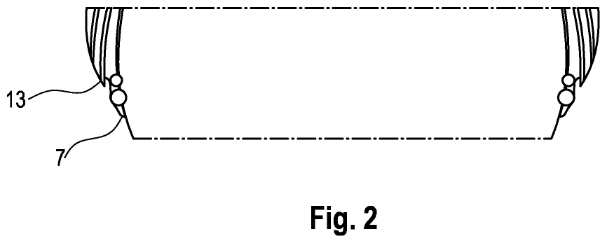

FIG. 2 shows that the end edges 13 and the ends 7 of the arms 6 are separated from one another. The ends of the channel 12 are oriented rather more away from one another in the outward direction, whereas the ends 7 of the arms 6 are oriented rather more towards one another in the inward direction.

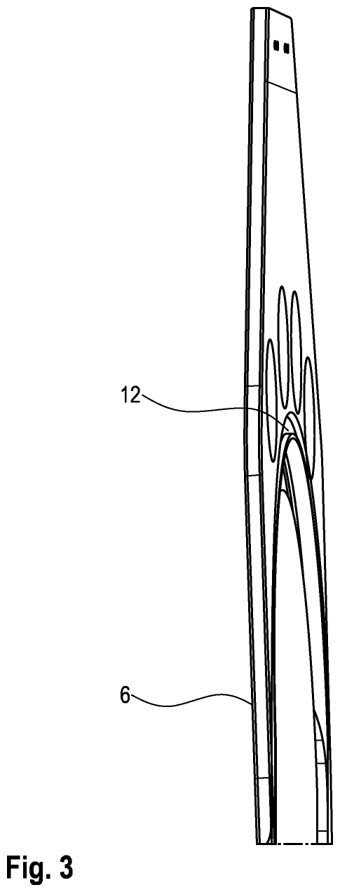

FIG. 3 shows a perspective view in which the channel 12 can be seen to good effect.

As far as the edges 13, the channel 12 largely follows the curvature of the inner side 8 of the arms 6. According to the embodiment shown, the channel 12 projects some way towards out of the plane of the front side.

The path for liquid once the gripper 1 has been transported out of the cleaning module leads from the head section 3 of the body 2 predominantly along the channel 12 to the end edges 13. From there, the liquid drips back, for example, into the cleaning module. Residues of liquid on the semiconductor wafer 10 are significantly reduced.

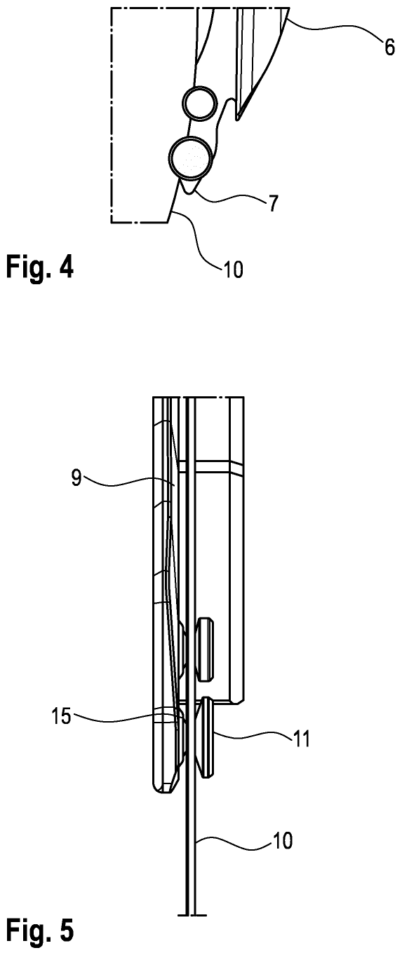

In the illustration according to FIG. 4, the arms 6, at the ends 7, are each tapered to a point 14, the latter having no contact with a semiconductor wafer 10 transported by the gripper. In the example shown, the point 14 is rounded. The point 14 may further be beveled, that is, have a decreasing thickness, the thickness decreasing with distance from the holding pins 11. Preferably, the upper surface of the point 14 shown in FIG. 4 is beveled.

FIG. 5 shows a preferred configuration of the holding pins 11, which holds a transported semiconductor wafer 10 at a distance from the supporting surface 9. The holding pins 11 each have a contact surface for the semiconductor wafer 10, the contact surface being flanked by boundaries. The boundaries are in the form of truncated cones 15, which are located opposite one another, the base surfaces of the truncated cones 15 being located on the outside.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

1 gripper
2 body
3 head section
4 apertures
5 foot section
6 arms
7 ends
8 inner side
9 supporting surface
10 semiconductor wafer
11 holding pins
12 channel
13 end edge
14 point
15 truncated cone

1. A gripper for transporting a vertically standing semiconductor wafer, the gripper comprising:
a flat body having a head section and a foot section, which form a planar front side;
arms, which extend from the head section to spaced-apart ends in the foot section;
at end sections of the arms, a supporting surface, which is arranged so as to be set back from the plane of the front side;
holding pins, which are arranged on the end sections and are configured to establish a clamping connection between the semiconductor wafer and the body; and
a channel, which follows an inner side of the arms, is made in the arms, and terminates at end edges, wherein the end edges are separated from the ends of the arms.

2. The gripper according to claim 1, further comprising apertures in the head section.

3. The gripper according to claim 1, wherein the channel projects out of the plane of the front side.

4. The gripper according to claim 1, wherein the inner side of the arms is curved.

5. The gripper according to claim 1, wherein:
the arms, at the edge ends, are each tapered to a point, the point being configured to not have contact with the semiconductor wafer being transported by the gripper.

6. The gripper according to claim 1, wherein the holding pins are configured to hold the semiconductor wafer at a distance from the supporting surface.

7. A method for cleaning the semiconductor wafer in a cleaning line, the method comprising: transporting the semiconductor wafer in a vertically standing state out of a cleaning module of the cleaning line using the gripper according to claim 1.
